(19) United States
(12) Patent Application Publication
(10) Pub. No.: US 2006/0268516 A1
(43) Pub. Date: Nov. 30, 2006

(54) Personal computer power supply unit

(75) Inventor: William Wong, Milton Keynes (GB)

Correspondence Address: HARRINGTON & SMITH, LLP, 4 RESEARCH DRIVE, SHELTON, CT, 06484-6212, US

(73) Assignee: High Performance Enterprise PLC

(21) Appl. No.: 11/341,967

(22) Filed: Jan. 26, 2006

Related U.S. Application Data
(63) Continuation-in-part of application No. 11/246,650, filed on Oct. 6, 2005.

(30) Foreign Application Priority Data
Jan. 31, 2005 (CN) 200542054
Nov. 16, 2005 (GB) 0523355.6

(51) Int. Cl. H05K 7/20

(52) U.S. Cl. 361/695

(57) ABSTRACT

A power supply unit includes a housing, an input power connection and six male output power connectors. They can have different numbers of pins, for providing power to different types of components. The connector includes four pins. The output power connector also includes a metallic tube, fixed in relation to the housing. The tube has a generally smooth inner surface, and a threaded outer surface. Connected to the tube on the interior surface thereof is a raised ridge, which ends a few millimetres short of the end face of the tube. In this way, a body of a corresponding connector is able to be received with the tube component only up to a few millimetres depth. The ridge cooperates with a channel on the corresponding connector. This prevents the corresponding connector being inserted fully unless correct orientation is present. An internally threaded and freely rotatable metal collar of the corresponding connector engages with the thread on the exterior of the tube to secure the connectors together.

### FIELD OF THE INVENTION

This invention relates to a personal computer power supply unit, and in particular to a power supply unit including plural output power connectors.

### BACKGROUND OF THE INVENTION

It is usual for the power supply unit of a personal computer system, such as a desktop or tower computer system, to comprise a generally cuboid metal housing, an input power connection and plural output power connectors. Until recently, the output power connectors have always taken the form of a small bundle of cables extending from the housing for some distance, typically around 100 mm, and each terminating with a respective connector. A power supply unit normally comprises between five and ten such output power connectors, so a significant number of wires are left trailing from the housing. Components of the personal computer which are required to be powered are coupled by a respective cable to one of the connectors hanging from the power supply unit. Many millions of such power supply units have been sold worldwide to date. Recently, a power supply named X-Connect has been released by Ultraproducts of Fletcher, Ohio (www.ultraproducts.com). This power supply is absent of trailing cables. Instead, the housing includes a number of female connector plugs, each of which his operable to receive a corresponding male connector and thereby link the power supply to a component of a personal computer. A similar power supply has recently been released by Thermal Take Technology Co. Ltd (www.thermaltake.com). The relevant power supply is called PurePower PWV500 series.

The inventor has identified some possible shortcomings with the prior art power supplies, and the present invention addresses the shortcomings.

### SUMMARY OF THE INVENTION

According to the present invention there is provided a personal computer power supply unit comprising:
a housing;
an input power connection; and
plural output power connectors each operable to mate with a respective corresponding connector;
   characterised in that each of the plural output power connectors is supported in a respective aperture in the housing and in that each of the output power connectors includes securing means for securing the respective output power connector to a corresponding external connector of a power cable.

Such a power supply unit needs not include any trailing wires therefrom, which can result in improved tidiness and reduced overall size. The simpler structure results in a power supply unit can be easier and less expensive to manufacture. Furthermore, since external cables are able to be secured to the power supply unit, the possibility of a cable working free from the power supply unit is eradicated. This can also provide more reliable electrical connection between corresponding terminals of the two connectors. Accordingly, the power supply unit can contribute towards a sturdy power supply system with reliable power supply/cable connections yet which is tidy and does not involve unnecessary cabling.

In a conventional friction fit connector arrangement, a proper, reliable connection is made is when two connectors are fitted together fully. If the fitting is less than full, electrical connection can be made through a smaller contact area. This can result in a higher electrical resistance. This in turn can lead to heating of the connector by the electrical power being carried thereby, which clearly is undesirable, and in reduced efficiency of power transmission. These problems are not normally noticeable to a user so no action to make better the connection will normally be taken. A smaller area of electrical contact also means that the connection is more vulnerable to being weakened further or broken, for instance as a result of vibration or jolting. When this happens, it could result in irreversible damage to the component whose power supply is suddenly removed. Even if the connection is broken when no power is not being supplied, it can be of considerable difficulty and inconvenience to determine what the fault is and to fully fit the connectors. All of these problems can be avoided by ensuring that the connectors are fully fitted together.

However, the securing means eliminates the possibility that an unreliable electrical connection will be made. Thus, a power supply unit according to the invention can avoid the above-mentioned problems sometimes found with friction fit connectors.

Preferably at least two of the output power connectors have different configurations. This can allow the power supply unit to be used to power personal computer components which have different power supply requirements, whilst avoiding the possibility of the cables being connected to wrong ones of the output power connectors of the power supply unit. At least two of the output power connectors may have different numbers of terminals. This can further reduce the possibility of a cable being connected to a wrong output power connector of a power supply unit.

One or more of the output power connectors may each have an orientation device arranged to allow an external connector to meet with it only when in a desired orientation. This can allow the possibility of a connector on a cable being connected the wrong way round to be eliminated. The orientation device may comprise a protrusion on either the connector on the power supply unit or the corresponding connector on a cable, and a corresponding indentation on the other connector.

The securing means of each of one or more output power connectors may include one or more pins each engageable with a J-shaped slot in a corresponding external connector. This can provide reliable securing of the two connectors by a user with one hand in a single action. The one or more pins of each of one or more of the output power connectors may be supported in a fixed position in relation to its output power connector.

Alternatively, the securing means of each of one or more output power connectors may include a screw thread able to secure the output power connector to an external connector by engaging with a corresponding screw thread thereon. Preferably, the screw thread of each of one or more of the output power connectors is supported in a fixed position in relation to its output power connector. This means that the power supply does not need to include any moving parts in the output power connectors.

The invention also provides a system comprising a power supply unit as described above and one or more power cables each including a connector operable to mate with one of the output power connectors.

In such a system and when a screw thread in each of one or more of the output power connectors is supported in a fixed position in relation to its output power connector, one or more of the power cables may include a screw thread freely rotatable in relation to its connector. This provides a convenient arrangement in which to connect a connector on a power cable with an output connector on the power supply unit. In particular, the body of the connector on the power cable may be mated with the connector on the power supply unit, the freely rotatable screw thread on the connector on the power cable being used to secure the two connectors together.

In such a system where one or more pins are engageable with one or more J-shaped slots, the connector of each of one or more of the power cables may include a J-shaped slot in a sheath that is rotatable in relation to the connector. This allows a reliable electrical connection to be made by a user in a straightforward manner.

Embodiments of the present invention will now be described, by way of example only, with reference to the accompanying drawings.

### BRIEF DESCRIPTION OF THE DRAWINGS

In the drawings:

FIG. 1 illustrates an exterior view of first and second embodiments of a power supply unit in accordance with the invention;

FIG. 2 illustrates in detail a male connector forming part of the first embodiment of the power supply unit of FIG. 1;

FIG. 3 shows a female connector connected at one end of a cable and operable to mate with the FIG. 2 male connector;

FIG. 4 illustrates in detail a male connector forming part of the second embodiment of the power supply unit of FIG. 1;

FIG. 5 shows a female connector connected at one end of a cable and operable to mate with the FIG. 4 male connector; and

FIG. 6 shows the FIG. 4 male connector mated with the FIG. 5 female connector.

### DETAILED DESCRIPTION OF THE PREFERRED EMBODIMENTS

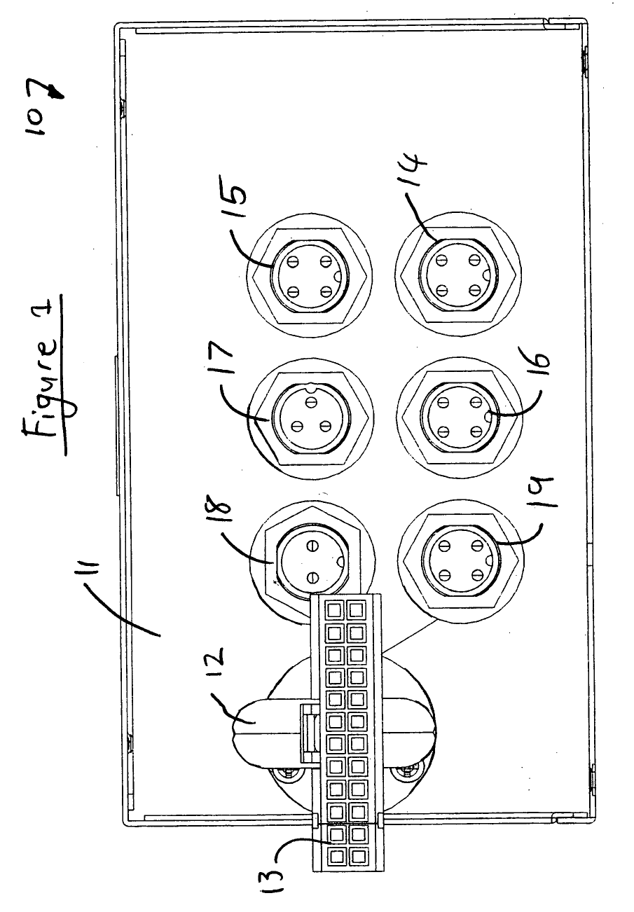

Referring firstly to FIG. 1, a power supply unit 10 is illustrated comprising a housing 11, an input power connection cable 12, an input power connection terminal 13 and first to sixth output power connectors 14 to 19. The housing 11 is in the form of a generally rectangular box, although only one face thereof is shown in FIG. 1. The housing 11 contains a transformer and all of the other conventional components of a power supply unit. The input power connection terminal 13 may be a 20-pin terminal. Alternatively, it may be a 24-pin terminal. Preferably, however, it is a terminal which is able to be a 20-pin terminal or a 24-pin terminal, so as to be universally useable.

All of the output power connectors 14 to 19 are male connectors. Accordingly, each includes a plurality of pins. The first, second third and sixth connectors, 14, 15, 16 and 19 are shown with four pins each. These connectors are suitable for use in providing power to a cable which has a molex connector at the other end. The fifth output power connector 19 has two pins. This is suitable for use in providing power to a cable for supplying a motherboard with power. The fourth connector 17 includes three pins. This is suitable for providing power to a PCI Express device. Alternatively, one of the power connectors can be provided with five pins, thereby making it suitable for use in providing power to a serial ATA (SATA) device.

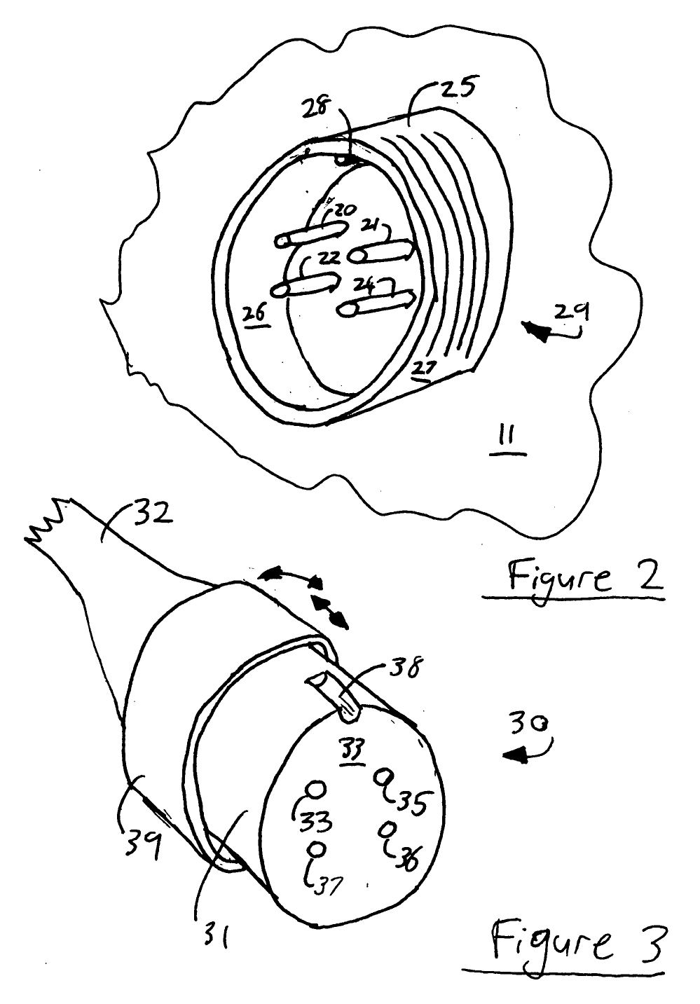

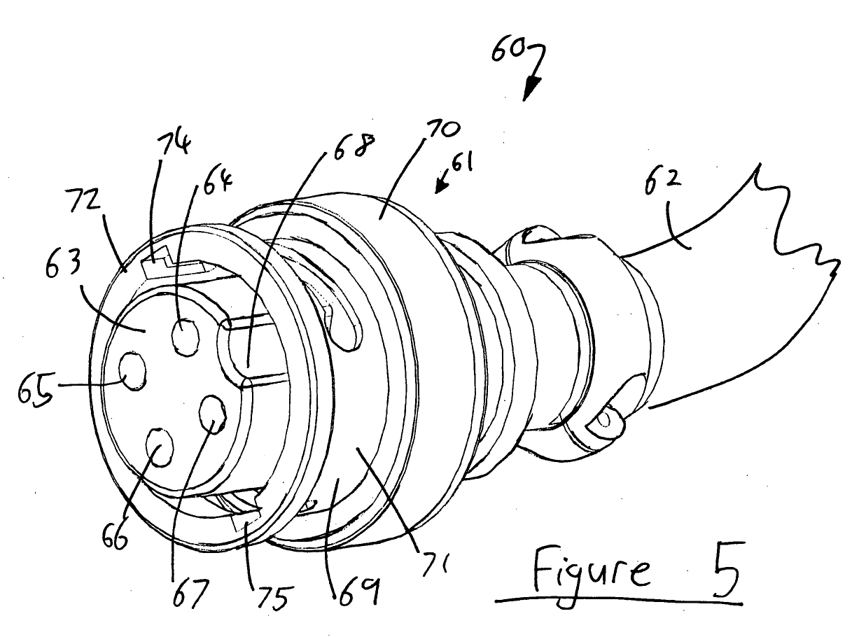

The first output power connector 14 of the first embodiment is shown in more detail in FIG. 2. The power connector 14 is referenced as 29 so as to distinguish it from the FIG. 4 power connector described below. Here, the connector 29 is shown standing proud of a face of the housing 11. The output power connector 29 includes first to fourth pins 20 to 24, arranged in the shape of a trapezium. The output power connector 29 also includes a metallic tube component 25, which is in a fixed position in relation to the housing 11 and has a long axis extending perpendicular to the face of the housing 11. The tube component 25 has a generally smooth inner surface 26, and a threaded outer surface 27. Connected to the tube component 25 on the interior surface 26 thereof is a protrusion 28. This protrusion takes the form a raised ridge 28 which extends in a direction parallel to the longitudinal axis of the tube component 25. The ridge 28 is relatively small, for example 0.5 mm in height and 5 mm long. The end of the ridge 28 which is furthest from the housing 11 does not extend to the end of the tube component 25. Instead, its end falls a few millimetres short of the end face of the tube component 25. In this way, a circular component having an external diameter the same as the internal diameter of the tube component 25 is able to be received within the tube component 25 up to a few millimetres depth, but is prevented from being placed any further therein by the ridge 28.

The other output power connectors 15 to 19 have a similar construction.

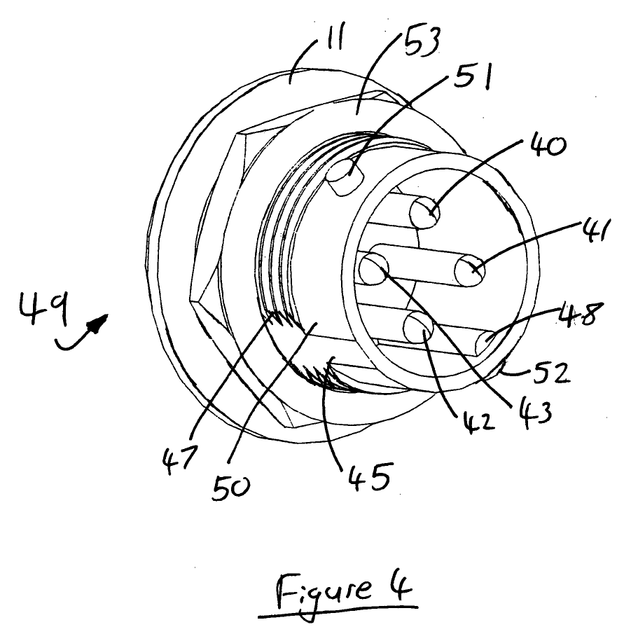

A connector 30 suitable for connection with the first output power connector 29 is illustrated at 30 in FIG. 3. The connector 30 includes a body 31, which is generally cylindrical in shape. The body 31 is coupled at a rear end to a cable 32. A front face 33 of the body 31 includes first to fourth terminal holes 34 to 37, each of which corresponds to and is mateable with one of the pins 20 to 24 of the FIG. 2 connector 29. Within the body 31, the terminals 34 to 37 are connected to respective cores of the cable 32.

The front face 33 of the body 31 is made of an enamel material, which provides electrical installation between the terminals 34 to 37. At one edge of the front face 33 is an opening to a channel 38, which extends for 5 mm in a direction parallel to the longitudinal access of the body 31. The channel 38 has dimensions corresponding to the dimensions of the ridge 28.

The connector 30 includes a metal collar 39. The collar 39 is freely rotatable around the body 31. The collar 39 is moveable in a direction along the longitudinal axis of the body 31. However, the collar 39 is limited to the extent in which it can move in this direction. In particular, it can move between a position at which its face furthest from the cable 32 is in generally the same plane as the plane of the face 33 of the body 31. In the opposite direction, the collar 39 can move more than 10 mm before it is prevented from moving any further.

The collar 39 may have a knurled exterior surface so as to provide a good surface for gripping by human figures. The interior surface of the collar 39 is provided with a screw thread having dimensions such that it is operable to engage with the screw thread on the exterior 27 of the tube component 25 of the output power connector 29.

To couple the connector 30 to the output power connector 29, a user may grasp the cable 32 or the body 31 and guide it towards the tube component 25 of the output power connector 29. Once the front face 33 of the body 31 is located within the interior of the tube component 25, the body 31 may be moved a few millimetres therealong. Movement will be prevented once the ridge 28 on the interior surface 26 on the tube component 25 is met by some part of the periphery of the front face 33 of the body 31. At this point, it will be necessary for the user to rotate the cable 32 or the body 31 and to apply a force towards the housing 11. Once the body 31 is rotated such that the channel 38 is aligned with the ridge 28, the body 31 will be allowed to move further towards the housing 11. At this alignment, the pins 20 to 24 are exactly aligned with the terminals 34 to 37, and are able to mate therewith. It is only when the ridge 28 is aligned with channel 38 that the pins 20 to 24 are aligned with terminals 34 to 37. Accordingly, the provision of the channel 38 and the ridge 28 ensures that a user does not try to force pins into wrong terminals in the connector 30. Furthermore, since the correct orientation can be assured, the possibility of power from the power supply being provided to wrong ones of the cores of the cable 32, by connection of wrong ones of the pins 20 to 24 to wrong ones of the terminals 34 to 37 can be avoided.

Preferably, the ends of the pins 20 to 24 which are furthest from the housing 11 are set back a small distance, for example, 1, 2 or 3 mm, from the end of the ridge 28 which is furthest from the housing. This ensures that the pins 20 to 24 do not contact any part of the face 33 of the body 31 until after the ridge 28 and the channel 38 are properly aligned.

Once the body 31 has been fully inserted into the tube component 25, the connectors 30 and 29 may be secured together. To achieve this, the user grasps the collar 39 and pushes it towards the housing 11. The thread on the exterior surface 27 of the tube component 25 will then be contacted by the corresponding thread on the interior surface of the collar 39. Once these two components connect, the user will need to rotate clockwise the collar 39 about the longitudinal axis of the body 31 so as to screw together the collar 39 and the tube component 25. Once the collar 39 has been fully screwed onto the tube component 25, the connector 30 is securely held in place with the output power connector 29.

To remove the connector 30 from the output power connector 29, the user rotates the collar 39 in the opposite direction, anti-clockwise, to unscrew it from the tube component 25. Once the collar 39 is fully unscrewed, which can be detected by the user since the amount of resistance to turning will suddenly be remove, the user can pull the cable 32, the collar 39 or the body 31 so as to extract the body 31 from within the tube component 25.

The first output power connector 14 of the second embodiment is shown in more detail in FIG. 4. The power connector 14 is referenced as 49 so as to distinguish it from the FIG. 2 power connector. Here, the connector 49 is shown standing proud of a face of the housing 11. The output power connector 49 includes first to fourth pins 40 to 44, arranged in the shape of a trapezium. The output power connector 49 also includes a metallic tube component 45, which is in a fixed position in relation to the housing 11 and has a longitudinal axis extending perpendicular to the face of the housing 11. The tube component 45 has a generally smooth inner surface 46. An outer surface is threaded at a part 47 closest to the housing 11, and has a non-threaded portion 50 between the threaded part 47 and the distal end of the tube component 45.

First and second locking pins 51, 52 are located opposite one another on the non-threaded portion and extending perpendicularly from the longitudinal; axis of the tube component 45. The locking pins 51, 52 are about as tall as they are wide. They are cylindrical in shape. The locking pins 51, 52 are not shown in FIG. 1.

A nut 53 is threaded onto the threaded part 47, thereby to secure the connector 49 to the housing 11 by reactive action against a flange (not shown) on the other side of the housing 11. The nut 53 includes notches (not shown) so as to allow it to be passed over the locking pins 51, 52.

Connected to the tube component 45 on the interior surface 46 thereof is a protrusion 48. This protrusion 48 takes the form a raised ridge which extends in a direction parallel to the longitudinal axis of the tube component 45. The ridge 48 is relatively small, for example 0.5 mm in height and 10 mm long. The end of the ridge 48 which is furthest from the housing 11 does not extend to the end of the tube component 45. Instead, its end falls between one and a few millimetres short of the end face of the tube component 45. In this way, a circular component having an external diameter corresponding to the internal diameter of the tube component 45 is able to be received within the tube component 45 up to a few millimetres depth, but is prevented from being placed any further therein by the ridge 48.

The other output power connectors 15 to 19 have a similar construction.

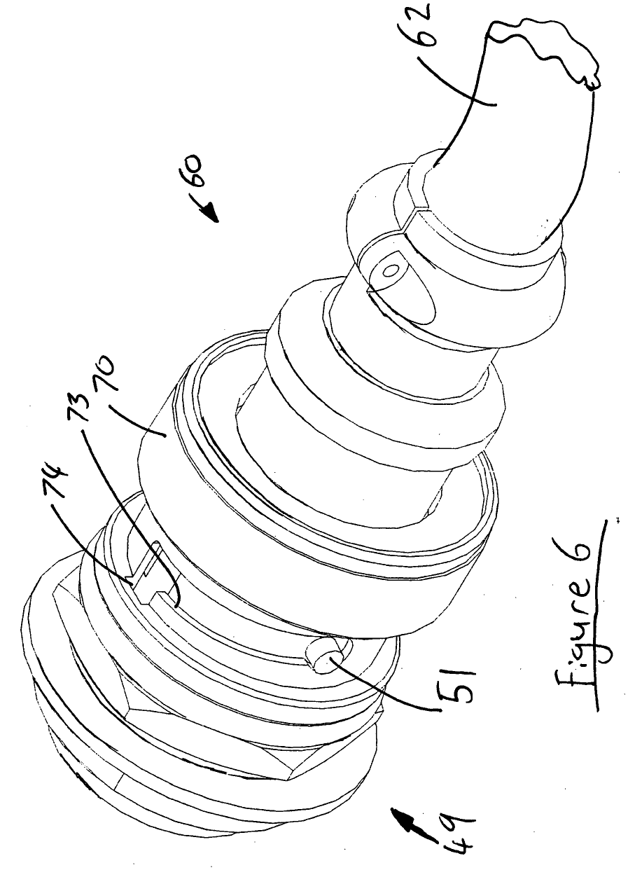

A connector 60 suitable for connection with the first output power connection 49 is illustrated at 60 in FIG. 5. The connector 60 includes a body 61. The body 61 is coupled at a rear end to a cable 62. A front face 63 of the body 61 includes first to fourth terminal holes 64 to 67, each of which corresponds to and is mateable with one of the pins 40 to 44 of the FIG. 4 connector 49. Within the body 61, the terminals 64 to 67 are connected to respective cores of the cable 62.

The front face 63 of the body 61 is made of an enamel material, which provides electrical installation between the terminals 64 to 67.

At one edge of the front face 63 is an opening to a channel 68, which extends for 5 mm in a direction parallel to the longitudinal access of the body 61. The channel 68 has dimensions corresponding to the dimensions of the ridge 48.

The connector 60 includes a metal collar 69. The collar 69 is freely rotatable around the body 61. The collar 69 is moveable in a direction along the longitudinal axis of the body 61. However, the collar 69 is limited to the extent in which it can move in this direction. In particular, it can move between a position at which its face furthest from the cable 62 is in generally the same plane as the plane of the face 63 of the body 61. In the opposite direction, the collar 69 can move only a few mm before it is prevented from moving any further. The collar is biased by a spring (not shown) or similar towards the cable 62 end of the body 61. The bias can be overcome on application of a force.

The collar includes a grip part 70, a pin locking part 71 and a flange part 72, each in a fixed position in relation to one another. The grip part 70 may have a knurled exterior surface so as to provide a good surface for gripping by human figures. The pin locking part 70 includes a J-shaped slot 73. An opening to the slot is provided by way of a notch 74 in the flange part 72. An opening 75 to a further J-shaped slot (not shown) on the opposite side of the collar 69 is provided in the flange part 72. The first J-shaped slot 73 extends from the notch first in parallel to the longitudinal axis of the body 61, then turns to extend around the circumference of the pin locking part 71 but spiralling slightly away from the flange part 72. The first J-shaped slot 73 extends for approximately one quarter of the circumference of the pin locking part 71. The end of the first J-shaped slot 73 which is distal to the notch 74 returns towards the flange part 72. The other J-shaped slot is identical and is located directly opposite the first J-shaped slot 73. In the below, engagement of the first locking pin 51 with the first J-shaped slot 73 will be understood also to involve simultaneous and identical engagement of the second locking pin 52 with the second J-shaped slot.

The first locking pin 51 when moving along the first J-shaped slot 73 from the end by the notch 74 extends firstly towards the cable 62 as the slot spirals then towards the flange part 72 as it reaches the end of the first J-shaped slot 73. When at the distal end of the first J-shaped slot 73, the first locking pin 51 is retained there by the bias of the collar 69 towards the cable 62. Thus, when the locking pins 51, 52 are engaged with the J-shaped slots, the female connector 60 is secured to the male connector 49 and the connectors cannot accidentally be separated.

The connection of the female connector 60 with the male connector 49 will now be described in detail. To couple the connector 60 to the output power connector 49, a user may grasp the cable 62 or the body 61 and guide it towards the tube component 45 of the output power connector 49. Once the front face 63 of the body 61 is located within the interior of the tube component 45, the body 61 may be moved a few millimetres therealong. Movement will be prevented once the ridge 48 on the interior surface 46 on the tube component 45 is met by some part of the periphery of the front face 63 of the body 61. At this point, it will be necessary for the user to rotate the cable 62 or the body 61 and to apply a force towards the housing 11. Once the body 61 is rotated such that the channel 68 is aligned with the ridge 48, the body 61 will be allowed to move further towards the housing 11 by a few mm or more. At this alignment, the pins 40 to 44 are exactly aligned with the terminals 64 to 67, and are able to mate therewith. It is only when the ridge 48 is aligned with channel 68 that the pins 40 to 44 are aligned with terminals 64 to 67. Accordingly, the provision of the channel 68 and the ridge 48 ensures that a user does not try to force pins into wrong terminals in the connector 60. Furthermore, since the correct orientation can be assured, the possibility of power from the power supply being provided to wrong ones of the cores of the cable 62, by connection of wrong ones of the pins 40 to 44 to wrong ones of the terminals 64 to 67, can be avoided.

Preferably, the ends of the pins 40 to 44 which are furthest from the housing 11 are set back a small distance, for example, 1, 2 or 3 mm, from the end of the ridge 48 which is furthest from the housing. This ensures that the pins 40 to 44 do not contact any part of the face 63 of the body 61 until after the ridge 48 and the channel 68 are properly aligned.

Since the movement of the collar 69 towards the cable 62 is limited and the collar 69 is biased towards the cable, the flange part 72 contacts the pins 51, 52 when the pins 40-43 are mated with the terminals 64-67 by a few mm. At this point, further movement of the body 60 is prevented. The user then rotates the collar 69 until the locking pins 51, 52 are aligned with the notches 74, 75 in the flange part 72. At this point, further movement of the female connector 60 towards the housing 11 is allowed. Once the user meets a stop formed by the change in direction between the part of the J-shaped slot 73 which is aligned with the entry notch 74 and the spiral part of the slot, the user rotates the collar 69 clockwise. This causes the locking pins 52, 52 to travel along the J-shaped slots 73 and to come to a rest at the end. The user releasing their grip on the female connector 60 then allows the bias of the collar 69 to retain the female connector 60 secured to the male connector 49.

FIG. 6 shows the male and female connectors 49, 60 secured together. It can be seen that the locking pin 51 is located at the end of the slot 73 distal to the entry notch 74.

To release the female connector 60 from the male connector 49, a user first grasps the grip part 70, pushes it towards the housing 11 against the bias and then rotates the collar 69 anti-clockwise. The rotation guides the locking pin 51 along the first J-shaped slot 73 until the corner between the spiral part of the slot and part of the slot that leads to the notch 74. The user can then remove the female connector 60 by withdrawing the collar 69, and thus the connector 60, away from the housing 11.

The locking pins 51, 52 and the J-shaped slots together comprise part of securing means which secure the male and female connectors 49, 60 together. The securing means is similar to that found in BNC connectors, although these are used with coaxial cables and are not conventionally used with power cables.

Although not shown, cable arrangements like the combination of the connector 30 and 32 are provided in respect of each of the other output power connectors 15 to 19. In each case, the pins and corresponding terminals are arranged such that they are directly aligned when a ridge on that output power connector 15 to 19 is aligned with a corresponding channel on the connector of the cable arrangement.

In a third embodiment, one or more of the male connectors 14-19 are like the FIG. 2 connector and the remaining connectors are like the FIG. 4 connector.

The power supply unit as described above and shown in the drawings does not need to include any trailing wires therefrom, which can result in improved tidiness and reduced overall size. This is achieved at the cost of volume within the housing of the PSU being used to accommodate parts of the connectors, but the inventor considers this acceptable in light of the advantages obtained.

The use of different numbers of pins on the connectors 14 to 19 helps to prevent components on a personal computer being connected to a wrong one of the output power connectors 14 to 19. Also, the provision of a ridge 28 with each of the output power connectors 14 to 19 allows wrong power connections to be avoided.

Each of the output power connectors 14 to 19 is provided in the housing 11. The output power connectors 14 to 19 are secured to the housing 11 in any suitable way. For tidiness, it is preferred that the output power connectors 14 to 19 are secured to the housing 11 by means located within the housing 11.

The simpler structure results in a power supply unit can be easier and less expensive to manufacture. Furthermore, since external cables are able to be secured to the power supply unit, the possibility of a cable working free from the power supply unit is eradicated. This also eliminates the possibility that connectors will be less than fully fitted together, which can provide more reliable electrical connection between corresponding terminals of the two connectors. Accordingly, the power supply unit can contribute towards a sturdy power supply system with reliable power supply/cable connections yet which is tidy and does not involve unnecessary cabling.

What is claimed is:

1. A personal computer power supply unit comprising:
a housing;
an input power connection; and
plural output power connectors each operable to mate with a respective corresponding connector;
wherein each of the plural output power connectors is supported in a respective aperture in the housing and in that each of the output power connectors includes securing means for securing the respective output power connector to a corresponding external connector of a power cable.

2. A power supply unit as claimed in claim 1, in which at least two of the output power connectors have different configurations.

3. A power supply unit as claimed in claim 2, in which at least two of the output power connectors have different numbers of terminals.

4. A power supply unit as claimed in claim 1, in which at least one of the output power connectors has a generally circular connection face.

5. A power supply unit as claimed in claim 4, in which at least one of the output power connectors has an orientation device arranged to allow an external connector to mate with it only when in a desired orientation.

6. A power supply unit as claimed in claim 1, in which the securing means of each of at least one output power connector includes at least two pins each engageable with a J-shaped slot in a corresponding external connector.

7. A power supply unit as claimed in claim 6, in which the at least two pins of each output power connector is supported in a fixed position in relation to its output power connector.

8. A power supply unit as claimed in claim 1, in which the securing means of each of at least one output power connector includes a screw thread able to secure the output power connector to an external connector by engaging with a corresponding screw thread thereon.

9. A power supply unit as claimed in claim 8, in which the screw thread of each output power connector is supported in a fixed position in relation to its output power connector.

10. A system comprising a power supply unit as claimed in claim 1, and at least one power cable, each such power cable including a connector operable to mate with one output power connector.

11. A system as claimed in claim 10, in which the securing means of each of at least one power connector includes a screw thread able to secure the output power connector to an external connector by engaging with a corresponding screw thread thereon and in which the connector of each of at least one of the power cables includes a screw thread freely rotatable in relation to the connector.

12. A system as claimed in claim 10, in which the securing means of each of one or more output power connectors includes one or more pins each engageable with a J-shaped slot in a corresponding external connector, and in which the connector of each of one or more of the power cables includes a J-shaped slot in a sheath that is rotatable in relation to the connector.
